(19) United States
(12) Patent Application Publication
(10) Pub. No.: US 2009/0277004 A1
(43) Pub. Date: Nov. 12, 2009

(54) TRANSFER PRODUCT, TRANSFER PRODUCT FABRICATION METHOD, AND TRANSFER PRODUCT ARRANGEMENT POSITION IDENTIFYING METHOD

(75) Inventors: Satoru Kotani, Osaka (JP); Keisuke Tanaka, Osaka (JP)

Correspondence Address: WENDEROTH, LIND & PONACK L.L.P., 1030 15th Street, N.W., Suite 400 East, Washington, DC, 20005-1503, US

(73) Assignee: PANASONIC CORPORATION, Osaka (JP)

(21) Appl. No.: 12/090,227

(22) PCT Filed: Oct. 6, 2006
(86) PCT No.: PCT/JP2006/320099

§ 371 Date: Apr. 14, 2008

(30) Foreign Application Priority Data
Oct. 12, 2005 (JP) 2005-298207

(51) Int. Cl. H05K 3/00

(52) U.S. Cl. 29/829

(57) ABSTRACT

It identifies the on-substrate arrangement position information of the transfer products which are fabricated on the same substrate without increasing the fabrication processes.

The process of repeatedly exposing a plurality of transfer product patterns which are depicted on a sheet of photo mask are repeatedly exposed on a substrate S times, and in at least two exposure processes among the S times exposure processes, photo masks on which different identification patterns are depicted for each of the plural transfer product patterns are employed to carry out the exposure processes repeatedly, and the number of transfer product patterns which are transferred at one time are differentiated between a process in the at least two exposure processes and the other processes.

### TECHNICAL FIELD

The present invention relates to a transfer product, a transfer product fabrication method, and a transfer product arrangement position identifying method which can identify the arrangement position even when after the chips are separated from the substrate.

### BACKGROUND ART

Recent years, in a fabrication process that produces transfer product from the same substrate through a plurality of transfer processes such as a semiconductor device fabrication process, in order to accelerate such as a fault analysis of a product, it has been required to identify the arrangement positions on the substrate of the respective transfer products, thereby to acquaint variation characteristics and inspection histories.

For example, Patent Document 1 discloses a method in which, in order to identify the arrangement position of the integrated circuit on a semiconductor wafer after assembly, checking number patterns which enable discrimination of integrated circuits on a semiconductor wafer are previously formed on a photo mask, the checking number patterns are transferred over all the integrated circuits on a wafer by one time exposure process, and the checking number patterns are read out, thereby the arrangement position on a wafer of the semiconductor integrated circuit is identified.

Further, in Patent Document 2, a method in which in order to identify the arrangement position of the integrated circuits on a semiconductor wafer after assembly, a wafer numbering process is provided at the manufacture of a semiconductor wafer so as to mechanically record a wafer number or a lot number at a non-chip region (comprising such as exposed aluminum film), and thereby the arrangement position of the semiconductor integrated circuit on a wafer is identified is disclosed.

In addition, in Patent Document 3, a method in which in order to enable to identify the arrangement position of the integrated circuit on a semiconductor wafer after assembly, regions on which identifier marks can be added in the fabrication processes are provided on the respective integrated circuits, and individual administration information on the manufacture concerning the particular chip such as lot number, wafer number, and position coordinates on a wafer, or test information such as test items and test results in the manufacture processes for the process TEG or the semiconductor integrated circuit, or combined information of these are written in for each semiconductor integrated circuit, and thereby the identification of the arrangement position of the semiconductor integrated circuit or the recording of inspection histories are carried out is disclosed.

### Patent Document 1: Japanese Patent No. 2964522 (Page 3, FIG. 1)

### Patent Document 2: Japanese Published Patent Application No. 11-45839 (Page 5, FIGS. 1 and 2)

### Patent Document 3: Japanese Published Patent Application No. 2000-228341 (Page 7, FIG. 1)

### DISCLOSURE OF THE INVENTION

### Problems to be Solved by the Invention

For example, in an integrated circuit that has installed a flash memory, there may be a method of writing data such as variation characteristics and inspection history of an integrated circuit into a specified region of a flash memory and utilizing the data. However, in an integrated circuit that has not yet installed a flash memory, it is not possible to employ a method of writing data into a specified region.

Conventionally, a method in which the checking number patterns that can identify the arrangement positions of integrated circuits are previously produced on a photo mask, the checking number patterns are transferred to all the integrated circuits on a wafer by a one time exposure process, and the numbers thereof are read out to identify the arrangement positions of the integrated circuits, a method of numbering wafers in the wafer numbering processes in the fabrication process of the semiconductor circuit, or a method of printing the control information directly by a laser, are employed for identification of the arrangement positions of the integrated circuits.

However, though the method recited in Patent Document 1 is effective in a fabrication method that carries out exposure of all the integrated circuits on a wafer in a one-time exposure process, in a method employing a stepper in which the photo masks are repeatedly moved and all the integrated circuits are being exposed, it is impossible to identify all the integrated circuits.

In addition, in the methods described in Patent Document 2 and Patent Document 3, though they are effective when the production number is less and the process number may be more or less increased with the correspondence being possible, when the production number is large, the addition of processes would occur an increase in the process number, thereby affecting the mass production number and resulting in problems. Accordingly, it is needed to provide a method that adds the arrangement information to the integrated circuit without increasing fabrication processes.

Further, in other than the semiconductor integrated circuit, in the processes of manufacturing transfer products which are produced on the same substrate through a plurality of transfer processes, in order to accelerate such as faulty analysis, it is required to identify the arrangement position of the integrated circuit on the substrate thereby to know the variation characteristics and inspection histories.

The present invention is directed to solving the problems described above and has for its object to provide a transfer product, a transfer product fabrication method, and a transfer product arrangement position identifying method that has enabled to distinguish the arrangement positions of the individual transfer products by the patterns which are produced in at least two fabrication processes.

### Measures to Solve the Problems

In order to solve the above-described problems, the present invention comprises a transfer product, that is obtained by carrying out a transfer process that transfer a desired transfer pattern which comprises arranging plural individual patterns in a lattice shape onto a substrate, with shifting the position on the substrate repeatedly, thereby to produce plural transfer products on the same substrate, wherein the transfer product has an arrangement position information representing the arrangement position on the substrate, which arrangement position information is produced through at least two times of transfer processes.

Thereby, without applying a process of performing marking so as to identify the arrangement position to a transfer product, it is possible to identify the arrangement position on the substrate of the transfer product.

According to claim 2 of the present invention, there is provided a transfer product as defined in claim 1, wherein the arrangement position information comprises a combination of respective identifiers which are added in the respective transfer processes in the at least two transfer processes, and the arrangement position information being different from each other for plural transfer products which are produced on the same substrate.

Thereby, without applying a process of performing marking so as to identify the arrangement position to a transfer product, it is possible to give, to the plural transfer products which are produced on the substrate, arrangement position information which are different from each other.

According to claim 3 of the present invention, there is provided a transfer product as defined in claim 2, wherein the identifier comprises identifier patterns which are arranged in a lattice shape in the desired transfer pattern corresponding to respective individual patterns, having been transferred onto the substrate, each of the identifier patterns being different for each the individual pattern which is included in the desired transfer pattern, and the number of the individual patterns which are transferred in each of the at least two transfer processes at one time is different in each of the at least two transfer processes.

Thereby, without applying a process of performing marking so as to specify the arrangement position to a transfer product, it is possible to give, to the plural transfer products which are produced on the substrate, the arrangement position information which are different from each other.

According to claim 4 of the present invention, there is provided a transfer product as defined in claim 3, wherein the product of the least common multiple of the numbers in the X axis direction and the least common multiple of the numbers in the Y axis direction of the individual patterns which are transferred at one time in each of the at least two transfer processes is larger than the total number of the transfer products which are produced on the same substrate.

Thereby, it is possible to give, to all the plural transfer products which are produced on the same substrate, different arrangement position information, and thereby it is possible to enhance the efficiency in producing the transfer products which can identify the arrangement positions on the same substrate.

According to claim 5 of the present invention, there is provided a transfer product as defined in claim 2, wherein the identifier is represented by resistance values which are produced in respective processes of the at least two transfer processes, and the arrangement position information comprises a combination of resistance values of resistor elements in respective processes of the at least two transfer processes.

Thereby, when the transfer product is a semiconductor integrated circuit, it is possible to read out resistance values from terminals in a package state after the semiconductor integrated circuit is assembled, and therefore, it is possible to identify the arrangement position on the substrate of the semiconductor integrated circuit without opening the package.

According to claim 6 of the present invention, there is provided a transfer product as defined in claim 2, wherein the identifier is one that is represented by values which are inherent to the memory elements, which values are constituted by one or more bits respectively and are produced in the two respective transfer processes, and the arrangement position information comprises a combination of values which are inherent to the memory elements in the at least two transfer processes.

Thereby, it is possible to digitally read out the arrangement position information and thereby it is possible to read out correct arrangement position information.

According to claim 7 of the present invention, there is provided a transfer product as defined in claim 2 wherein the identifier is one which is represented by code patterns which form parts of the two-dimensional code which are produced in the respective processes of the at least two transfer processes, and the arrangement position information is an information that is possessed by the two dimensional code which comprises a combination of the code patterns in the respective processes of the at least two transfer processes.

Thereby, since it is not possible to clarify the content of the two-dimensional code only by viewing the two-dimensional code, it is possible to enhance the safety in the security concerning the arrangement position information.

According to claim 8 of the present invention, there is provided a transfer product as defined in claim 1, wherein the transfer product includes substrate information which identifiably represents a substrate on which the transfer product is produced.

Thereby, it is possible to identify the arrangement position of the transfer product for those which are produced on different substrates.

According to claim 9 of the present invention, there is provided a transfer product fabrication method for fabricating a plurality of transfer products on a same substrate, which comprises repeating transfer steps each transferring a desired transfer pattern which comprises plural individual patterns arranged in a lattice shape onto a substrate with shifting the position thereof plural times, which further comprises producing an arrangement position information representing the arrangement position on the substrate of the transfer product onto each of the transfer products which are produced on the substrate through the at least two transfer steps.

Thereby, it is possible to manufacture a transfer product that can identify the arrangement position on the same substrate, without applying a process of performing marking so as to identify the arrangement position to the transfer product.

According to claim 10 of the preset invention, there is provided a transfer product fabrication method as defined in claim 9, wherein in each transfer step of the at least two transfer steps, respective identifiers forming the arrangement position information are produced for each of the plural transfer products which are produced on the substrate.

Thereby, it is possible to manufacture plural transfer products which have different arrangement position information on a substrate, without applying a process of performing marking so as to identify the arrangement position.

According to claim 11 of the present invention, there is provided a transfer product fabrication method for fabricating a plurality of transfer products on a same substrate as defined in claim 10, wherein the at least two transfer steps transfer identifier patterns which are arranged in a lattice shape in a desired transfer pattern corresponding to the respective individual patterns, the identifier patterns are all different for each individual pattern, and the number of the individual patterns which are transferred in each of the at least two transfer processes is different in each of the at least two transfer processes.

Thereby, it is possible to manufacture plural transfer products which have different arrangement position information on a substrate, without applying a process of performing marking so as to identify the arrangement positions.

According to claim 12 of the present invention, there is provided a transfer product fabrication method as defined in claim 11, wherein the product of the least common multiple of the numbers in the X axis direction and the least common multiple of the numbers in the Y axis direction of the individual patterns which are transferred at one time in each of the at least two transfer processes is larger than the total number of the transfer products which are produced on the same substrate.

Thereby, it is possible to give, to all the plural transfer products which are produced on the same substrate, different arrangement position information, and thereby it is possible to enhance the efficiency in producing the transfer products which can identify the arrangement positions on the same substrate.

According to claim 13 of the present invention, there is provided a transfer product fabrication method as defined in claim 10, which further comprises producing resistor elements having inherent resistance values in respective steps of the at least two transfer steps, and adding, to each of the plural transfer products which are produced on the substrate, the arrangement position information which comprises a combination of the at least two resistor elements produced, respectively.

Thereby, when the transfer product is a semiconductor integrated circuit, it is possible to read out resistance values from terminals in a package state where the semiconductor integrated circuit is assembled, and therefore, it is possible to fabricate semiconductor integrated circuits that are capable of identifying the arrangement position on the substrate of each semiconductor integrated circuit, without opening the package.

According to claim 14 of the present invention, there is provided a transfer product fabrication method as defined in claim 10, further comprising producing memory elements which are constituted by one or more bits in each step of the at least two transfer steps, and adding, to each of the plural transfer products which are produced on the substrate, the arrangement position information which comprises a combination of the values of the at least two memory elements produced.

Thereby, it is possible to digitally read out the arrangement position information, and thereby it is possible to fabricate a transfer product that can read out correct arrangement position information.

According to claim 15 of the present invention, there is provided a transfer product fabrication method as defined in claim 10, which further comprises producing a code pattern which forms a part of a two-dimensional code which can be recognized from outside in respective steps of the at least two transfer steps, and adding, to each of the plural transfer products which are produced on the substrate, the arrangement position information that is represented by a two-dimensional code which is a combination of the at least two code patterns formed.

Thereby, since it is not possible to clarify the content of the two-dimensional code only by viewing the two-dimensional code, it is possible to enhance the safety in the security concerning the arrangement position information.

According to claim 16 of the present invention, there is provided a transfer product fabrication method as defined in claim 9, which further comprises adding, to each of the plural transfer products, substrate information that represents the substrate on which the transfer product is formed identifiably.

Thereby, it is possible to manufacture a transfer product that is capable of identifying the arrangement position of the transfer product which are produced on different substrates.

According to claim 17 of the present invention, there is provided a transfer product arrangement position identifying method for identifying the transfer product arrangement position on the substrate, comprising carrying out a transfer process that transfers a desired transfer pattern that has arranged plural individual patterns in a lattice shape onto a substrate, with shifting the position on the substrate repeatedly, which further comprises reading out a combination of at least two identifiers which are produced on the plural transfer products in each of the at least two transfer processes, so as to identify the arrangement position on the substrate.

Thereby, it is possible to identify the arrangement position on the substrate of the transfer product after the plural transfer products which are produced on the same substrate are cut out from each other.

According to claim 18 of the present invention, there is provided a transfer product arrangement position identifying method as defined in claim 17, wherein the identifier is represented by resistance values which are produced in respective processes of the at least two transfer processes, and the arrangement position is identified on the basis of a combination of resistance values of at least two resistor elements.

Thereby, when the transfer product is a semiconductor integrated circuit, it is possible to read out resistance values from terminals in a package state where the semiconductor integrated circuit is assembled, and therefore, it is possible to identify the arrangement position on the substrate of the semiconductor integrated circuit, without opening the package.

According to claim 19 of the present invention, there is provided a transfer product arrangement position identifying method as defined in claim 17, wherein the identifier is represented by values which are inherent to the memory elements which values are constituted by one or more bits respectively, and which values are produced in respective processes of the at least two transfer processes, and the method further comprises identifying the arrangement position on the substrate on the basis of the combination of values of the at least two memory elements.

Thereby, it is possible to digitally read out the arrangement position information and thereby it is possible to read out correct arrangement position information.

According to claim 20 of the present invention, there is provided a transfer product arrangement position identifying method as defined in claim 17, wherein the identifier is one which is represented by code patterns which form parts of the two-dimensional code which are produced in the respective processes of the at least two transfer processes, and the method further comprises identifying the arrangement position on the substrate on the basis of the information that is possessed by the two-dimensional code which comprises a combination of the at least two code patterns.

Thereby, since it is not possible to clarify the content of the two-dimensional code only by viewing the two-dimensional code, it is possible to enhance the safety in the security concerning the arrangement position information.

### EFFECTS OF THE INVENTION

According to the present invention, the transfer processes which expose desired transfer patterns comprising plural individual patterns on a substrate are repeatedly carried out in S times, and in at least two transfer processes among the S times transfer processes, identifier patterns which are arranged in a lattice shape corresponding to plural individual patterns are exposed onto a substrate, and in each of the at least two exposure processes, the respective identifier patterns are made different from each other, as well as the numbers of the individual patterns which are transferred together at one time are differentiated. Thereby, it is possible to produce individual identifiers comprising at least two identifiers onto the plural transfer products which are produced on the substrate, thereby enabling to easily identify the arrangement position of the transfer products on the same substrate, without increasing the fabrication processes.

Further, since the numbers of the individual patterns which are included in the transfer patterns which are transferred in each of the at least two transfer processes that expose identifier patterns is made such that the product of the least common multiple of the numbers in X axis direction and the least common multiple of the numbers in the Y axis direction, of the respective transfer patterns which are transferred at once in each of the at least two transfer processes is larger than the total number of the transfer products which are produced on the same substrate, it is possible to add individual identifiers which can identify each of the transfer products to all the transfer products which are produced on the substrate, and thereby it is possible to efficiently produce transfer products which have individual identifiers on a piece of substrate.

Further, when for example the transfer product is a semiconductor integrated circuit, by the individual identifier being constituted by a resistor element, it is possible to read out resistance values from the terminals in a package state after the semiconductor integrated circuit is assembled, it is possible to manufacture a semiconductor integrated circuit that is capable of identifying the on-substrate arrangement position of the semiconductor integrated circuit even in a state where the package is not yet opened.

Further, when the transfer product is a semiconductor integrated circuit, since the individual identifier is constituted by a memory element and thereby it is possible to read out the individual identifier ID digitally, the value of the memory element can be read out from the terminal in a package state after the semiconductor integrated circuit is assembled, and thereby it is possible to enhance the analysis precision when identifying the arrangement position of the semiconductor integrated circuit.

Further, by that the individual identifier is constituted by a two-dimensional code, there is no danger that the content thereof is known to a person who is not controlling the content of the two-dimensional code, and thereby, it is possible to increase the safety in the security concerning the administration of the arrangement position information.

### BRIEF DESCRIPTION OF THE DRAWINGS

FIG. 1(a) is a diagram illustrating a construction of a semiconductor integrated circuit according to a first embodiment of the present invention.

FIG. 1(b) is a diagram illustrating a semiconductor integrated circuit according to a first embodiment of the present invention.

FIG. 1(c) is a diagram illustrating the relation between an identifier and a resistance value.

FIG. 2 is a diagram illustrating a semiconductor integrated circuit that is produced on a wafer.

FIG. 3(a) is a plan view showing a photo mask for producing an identifier according to the first embodiment.

FIG. 3(b) is a plan view showing a photo mask for producing an identifier according to the first embodiment.

FIG. 4 is a diagram schematically showing the transition of exposure of the semiconductor integrated circuit.

FIG. 5(a) is a plan view showing a wafer which is exposed by using photo mask M1.

FIG. 5(b) is a plan view showing a wafer which is exposed by using the photo mask M2.

FIG. 6 is a diagram schematically showing the transition of exposure of the semiconductor integrated circuit.

FIG. 7(a) is a diagram illustrating a construction of a semiconductor integrated circuit having identification trace for identifying a wafer.

FIG. 7(b) is a diagram illustrating a construction of a semiconductor integrated circuit having an identification trace for identifying a wafer.

FIG. 8(a) is a diagram illustrating a construction of an individual identifier in the first embodiment.

FIG. 8(b) is a diagram illustrating a construction of an individual identifier in the first embodiment.

FIG. 8(c) is a diagram illustrating a construction of a semiconductor integrated circuit after the packaging.

FIG. 9(a) is a diagram illustrating a construction of an individual identifier in the second embodiment.

FIG. 9(b) is a diagram illustrating a construction of an individual identifier in the second embodiment.

FIG. 9(c) is a diagram illustrating a construction of a semiconductor integrated circuit after the packaging.

FIG. 10(a) is a diagram illustrating a construction of an individual identifier in the third embodiment.

FIG. 10(b) is a diagram illustrating a construction of an individual identifier in the third embodiment.

FIG. 11(a) is a diagram illustrating a conventional photo mask for producing a semiconductor integrated circuit.

FIG. 11(b) is a diagram illustrating a conventional photo mask for producing a semiconductor integrated circuit.

FIG. 11(c) is a diagram illustrating a conventional semiconductor integrated circuit produced on a wafer.

### DESCRIPTION OF REFERENCE NUMERALS

IC[n] . . . semiconductor integrated circuit
CI[n] . . . circuit portion
ID[n] . . . individual identifier
CPi<j> . . . circuit portion
Pi<j> . . . integrated circuit pattern
Fa<j> . . . a-th identifier pattern
Ma . . . photo mask
701 . . . identification trace
801a . . . first resistor element
801b . . . second resistor element
802, 903 . . . setting register
803a-803d . . . selector
8A-8E and 9A-9I . . . terminal
901a . . . first memory element
901b . . . second memory element
902a-902h . . . selector
1001, 1002 . . . two-dimensional code

### BEST MODE TO EXECUTE THE INVENTION

The present invention is one that enables to identify the arrangement positions on the substrate of the respective transfer products, which are produced on the same substrate by a transfer process transferring plural patterns on the substrate simultaneously in plural times as in one that employs exposure processes such as the manufacture of a semiconductor integrated circuit, a panel, an MEMS (Microelectro Mechanical Systems), and a thin film or a film, or one that employs printing processes such as the manufacture of a color printer or a print circuit board.

Hereinafter, embodiments of the present invention will be described with reference to the drawings. Herein, descriptions are given with raising a semiconductor integrated circuit as a transfer product according to the present invention. Herein, the embodiments shown herein are only examples, and the present invention is not necessarily limited to those embodiments.

### First Embodiment

First of all, a general fabrication method of a transfer product will be described with raising a fabrication method of a semiconductor integrated circuit as an example.

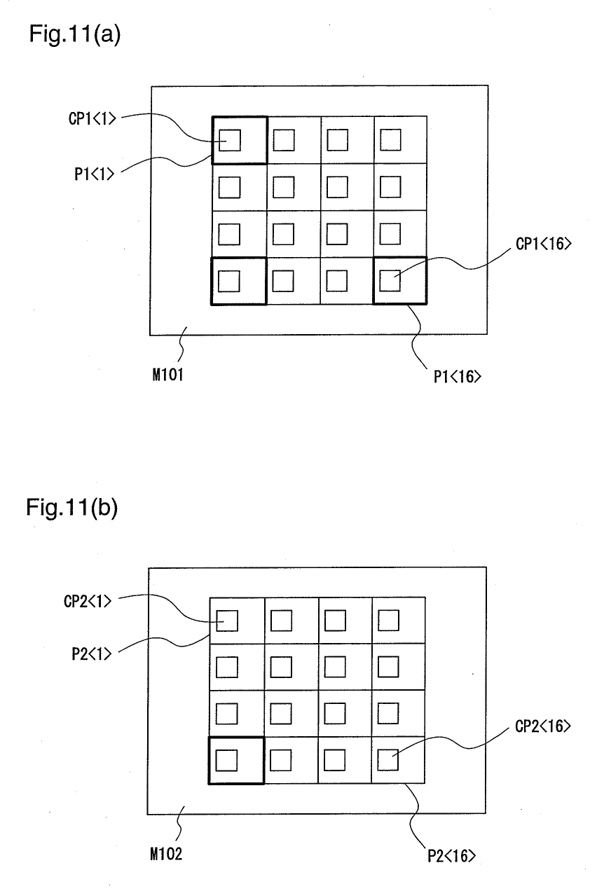

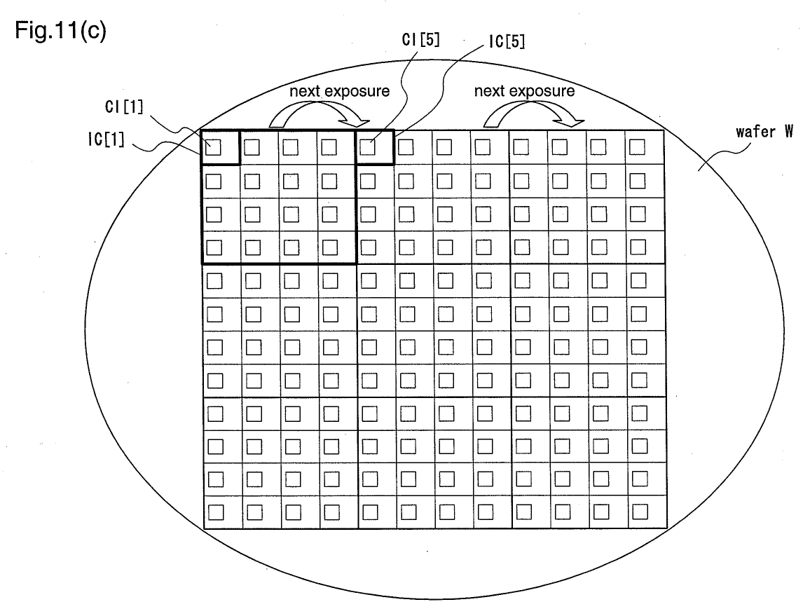

FIG. 11(a) is a diagram illustrating a photo mask M101 that is employed in a first process in producing a semiconductor integrated circuit. On the photo mask M101, 16 pieces of integrated circuit patterns P1<1> to P1<16> are depicted, and on respective integrated circuit patterns P1<1> to P1<16>, circuit portions CP1<1> to CP1<16> of the semiconductor integrated circuit are depicted, respectively.

FIG. 11(b) is a diagram illustrating a photo mask M102 that is employed in a second process in producing a semiconductor integrated circuit. Similarly as in the photo mask M101, 16 pieces of integrated circuit patterns P2<1> to P2<16> are depicted on the photo mask M102, and on respective integrated circuit patterns P2<1> to P2<16>, portion circuit patterns CP2<1> to CP2<16> of the semiconductor integrated circuit are depicted, respectively.

FIG. 11(c) is a plan view illustrating a substrate (wafer) W in a general fabrication process of a semiconductor integrated circuit. On a sheet of wafer W, n (n≧2) pieces of semiconductor integrated circuits IC[k] to IC[n] are produced through plural exposure processes. FIG. 11 illustrates a state where the 144 pieces of semiconductor integrated circuits IC[1] to IC[144] are formed.

While a general fabrication method of a semiconductor integrated circuit comprises, at first, performing exposure using the photo mask M101 in the first exposure process, in that first exposure process, exposure is repeated with changing the exposure position until integrated circuit patterns of the number that can be produced as much as possible using the photo mask M101 are produced, thereby transferring integrated circuit patterns P1<1> to P1<16> onto the wafer W. Next, exposure is repeated with changing the exposure position until integrated circuit patterns of the number that can be produced as much as possible using the photo mask M102 are produced, thereby transferring integrated circuit patterns P2<1> to P2<16> onto a wafer W.

Henceforth, by performing plural exposure processes which are required for producing a semiconductor integrated circuit similarly as above, the 144 pieces of semiconductor integrated circuits IC[1] to IC[144] are finally formed on a substrate wafer W.

In this way, conventionally, the number of transfer patterns of the transfer products which are transferred through a one-time exposure or printing process is the same for any of the exposure processes. Accordingly, it was difficult to identify the arrangement positions of the transfer products which are produced on the same substrate after the transfer products are cut out from the substrate, unless such as marking is performed to each transfer product by a separate process.

The fabrication method of a transfer product according to the first embodiment comprises, for example, a fabrication method of a semiconductor integrated circuit in which at least two exposure processes each of which employs a photo mask on which an integrated circuit pattern and a pattern for producing an identifier are depicted, and the individual identifier comprising a combination of identifiers are added to all the n pieces of semiconductor integrated circuits IC[1] to IC[n] which are produced on the same substrate.

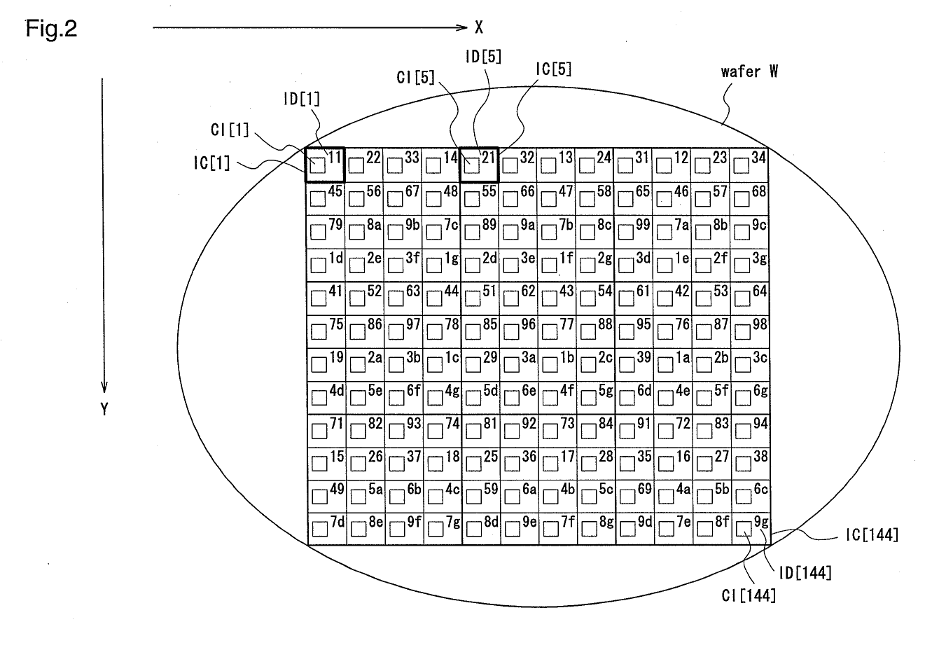

FIG. 2 is a plan view illustrating a wafer W1 on which the semiconductor integrated circuits IC[1] to IC[n] according to the first embodiment are formed. As shown in FIG. 2, the semiconductor integrated circuits IC[1] to IC[144] are formed in rectangular configurations, respectively, on a wafer W. In the first embodiment of the present invention, the semiconductor integrated circuit at the left corner is represented as IC[1], and those formed at towards right subsequent thereto are represented as IC[2], IC[3], . . . , IC[144], respectively. Further, in FIG. 2, the rightward direction from the semiconductor integrated circuit IC[1] is defined as X axis direction, and the downward direction from that is defined as Y axis direction, respectively.

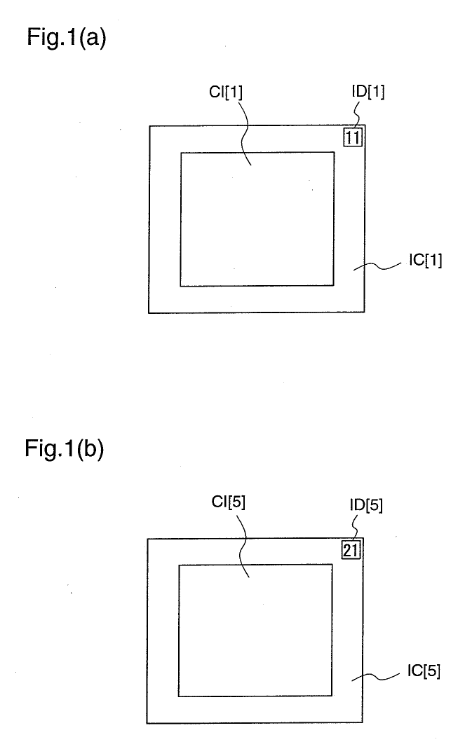

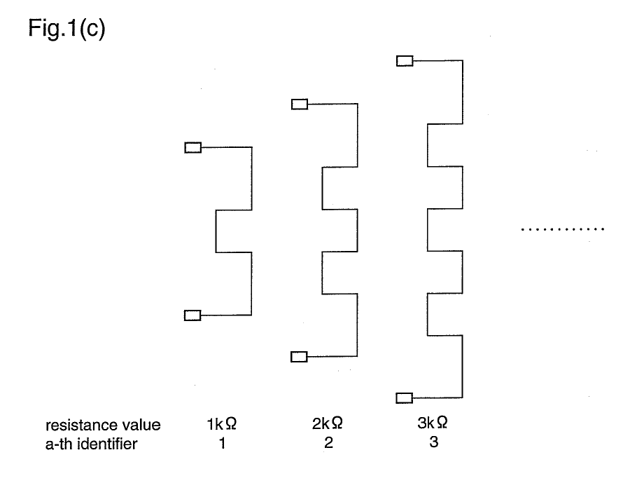

FIGS. 1(a) and 1(b) are diagrams illustrating a semiconductor integrated circuit IC[1] and a semiconductor integrated circuit IC[5] according to the first embodiment, respectively.

On the semiconductor integrated circuit IC[1], the circuit portion CI[1] which is common through the semiconductor integrated circuits IC[1] to IC[144] and the individual identifier ID[1] which is an arrangement position information that is required for identifying the arrangement position on the wafer W are formed. In addition, on the semiconductor integrated circuit IC[5], the circuit portion CI[5] which is common through the semiconductor integrated circuits IC[1] to IC[144] and the individual identifier ID[5] which is an arrangement position information that is required for identifying the arrangement position on the wafer W are formed.

In this way, on the respective semiconductor integrated circuits IC[k] which are produced on a wafer W, the circuit portion CI[k] which is common through all the semiconductor integrated circuits IC[1] to IC[n], and the individual identifier ID[k] which is inherent to each of the semiconductor integrated circuits IC[1] to IC[n] and is an arrangement information that is required to specify the arrangement position on the wafer W, are formed.

Specifically, the individual identifier ID[k] is constituted by a resistor circuit which has a (a≧=2) pieces of resistor elements. In this first embodiment, identifiers F are assigned with corresponding to the resistance values of these a pieces of resistor elements, and the first identifier F1 to the a-th identifier Fa are sequentially arranged in parallel from right to left, thereby displaying the individual identifier ID[k].

FIG. 1(c) is a diagram representing the relation between the resistor element and the identifier F.

As shown in FIG. 1(c), in this first embodiment, the a-th identifier Fa is represented by an alpha numeric or an alphabet that corresponds to the resistance value of the resistor element. The individual identifier ID[k] comprises a combination of these values.

For example, in FIG. 1(a), the individual identifier ID[1] having a display of “11” represents that a resistor element of 1 kΩ that is represented by “1” is provided as a first identifier F1, and that a resistor element of 1 kΩ that is represented by “1” is provided as a second identifier F2, respectively. In addition, in FIG. 1(b), the individual identifier ID[5] having a display of “21” represents that a resistor element of 1 kΩ that is represented by “1” is provided as a first identifier F1, and a resistor element of 2 kΩ that is represented by “2” is provided as a second identifier F2, respectively. Herein, the details of the individual identifier ID[k] are described later.

Next, a fabrication method of a semiconductor integrated circuit IC[k] that is constituted as described above will be described.

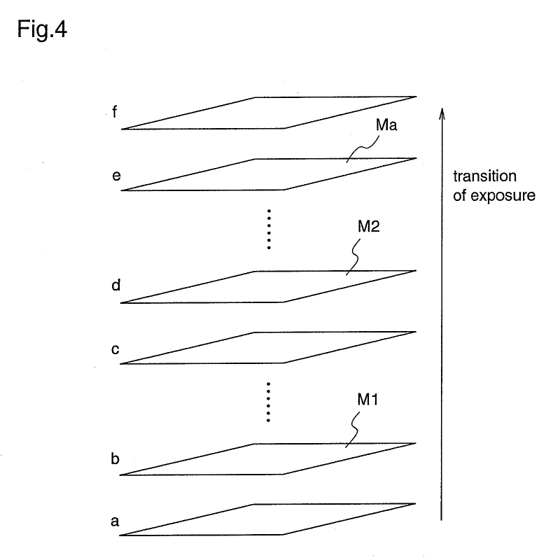

The fabrication method of a semiconductor integrated circuit according to the present invention comprises, when the semiconductor integrated circuits IC[1] to IC[n] on a wafer W are produced in S (S≧2) times exposure processes, performing a (a≧2) times identifier pattern exposure processes, employing photo masks M1 to Ma on which the circuit pattern CI and the first identifier F1 to a-th identifier Fa pattern are depicted, respectively, thereby producing the first identifier F1 to the a-th identifier Fa. This will be described with reference to FIG. 4.

FIG. 4 is a diagram illustrating transition of exposure processes when producing a semiconductor integrated circuit by S times exposure processes. In FIG. 4, a represents a first time exposure process, b to e represents a second time to S−1th time exposure processes, respectively, and f represents S time exposure process.

As shown in FIG. 4, the first identifier F1 is produced in the first identifier pattern exposure process b for carrying out exposure employing photo mask M1, the second identifier F2 is produced in the second identifier exposure process d for carrying out exposure employing photo mask M2, and with hereinafter similarly taking the process of carrying out exposure employing photo mask Ma on which the circuit pattern and the identifier pattern are depicted as a-th identifier pattern exposure process, the a-th identifier is produced in the a-th exposure process.

These first to a-th identifier pattern exposure processes are appropriately assigned in the S times exposure processes, and when the S times exposure processes are completed, the semiconductor integrated circuits IC[1] to IC[n] on each of which individual identifier ID[k] that comprises a combination of the first identifier F1, the second identifier F2, . . . , the a-th identifier Fa is produced are produced on a wafer W.

Hereinafter, a fabrication method of the semiconductor integrated circuit IC[k] will be described concretely.

As shown in FIG. 2, it is considered a case where 144 pieces of semiconductor integrated circuits IC[1] to IC[144] are produced on a substrate W, and the arrangement positions on the same wafer W of all the semiconductor integrated circuits IC[1] to IC[144] are identified. In order to realize this, it is required to assign different individual identifiers ID[1] to ID[144] to all the semiconductor integrated circuits IC[1] to IC[144].

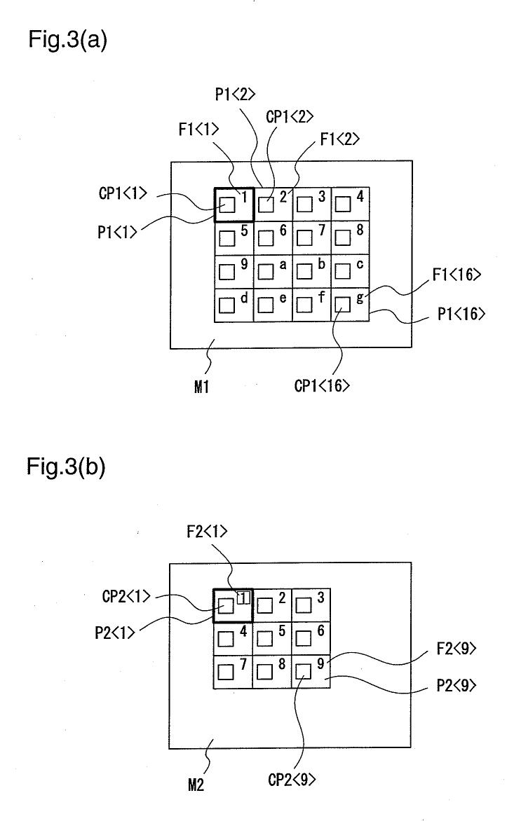

FIGS. 3(a) and 3(b) are plan views illustrating photo masks for producing individual identifiers ID[k], which are used in the exposure processes for producing the individual identifiers ID[k], where FIG. 3(a) represents a photo mask M1 that is used in the first identifier pattern exposure process, and FIG. 3(b) represents a photo mask M2 that is used in the second identifier pattern exposure process.

On the photo mask M1, there are totally 16 pieces of integrated circuit patterns P1<1> to P1<16> with 4 pieces arranged in the X axis direction and 4 pieces arranged in the Y axis direction depicted, and on the respective integrated circuit patterns P1<1> to P1<16>, identifier patterns F1<1> to F1<16> for producing the first identifier F1, which are represented by numerals of 1 to 9 and alphabets of a to g, and circuit patterns CP1<1> to CP1<16> are depicted. The identifier patterns F1<1> to F1<16> for producing the first identifier F1 are all different from each other on the photo mask M1.

On the photo mask M2, there are totally 9 pieces of integrated circuit patterns P2<1> to P2<9> with 3 pieces arranged in the X axis direction and 3 pieces arranged in the Y axis direction depicted, and on the respective integrated circuit patterns P2<1> to P2<9>, identifier patterns F2<1> to F2<9> for producing the second identifier F2, which are represented by numerals of 1 to 9, and circuit patterns CP2<1> to CP2<9> are depicted. The identifier patterns F2<1> to F2<9> for producing the first identifier F2 are all different from each other on the photo mask M2.

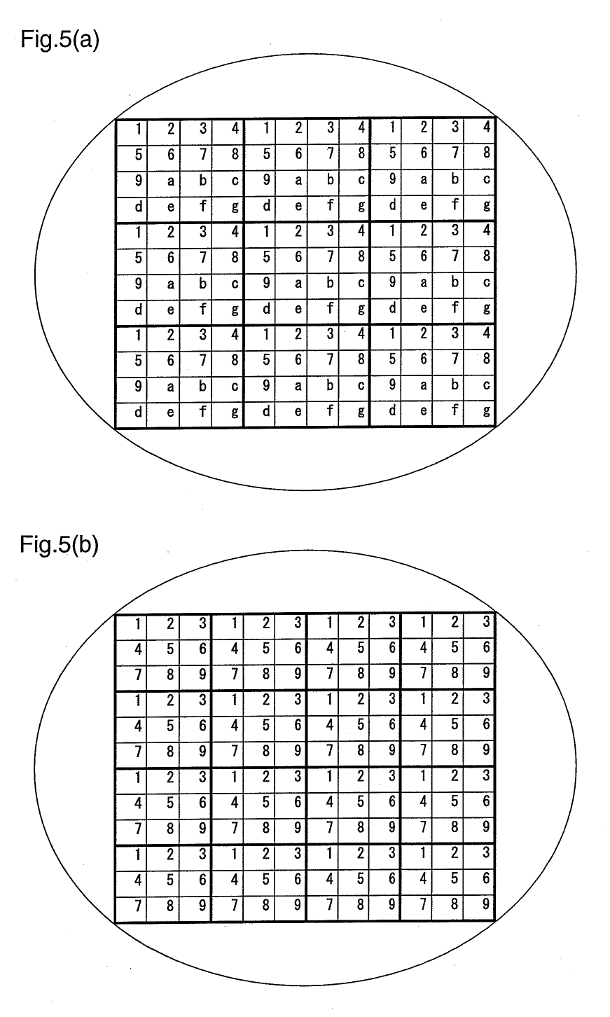

FIG. 5(a) is a plan view illustrating a wafer W which is subjected to exposure employing a photo mask M1. Only the first identifier F1 which was produced on the wafer W is represented in FIG. 5(a). When exposure is repeated with changing the exposure position until integrated circuit patterns of the number that can be produced by using the photo mask M1 as much as possible are produced and the exposure processes are completed, identifier patterns F1<1> to F1<16> positioning on the photo mask M1 are repeatedly transferred in a unit of 4×4 pieces of blocks onto the wafer W.

FIG. 5(b) is a plan view illustrating a wafer W which is subjected to exposure employing a photo mask M2.

When exposure is repeated with changing the exposure position until integrated circuit patterns of the number that can be produced by using the photo mask M2 are produced as much as possible, and when the exposure processes are completed, identifier patterns F2<1> to F2<9> positioning on the photo mask M2 are repeatedly transferred in a unit of 3×3 pieces of blocks onto the wafer W.

In this way, the 16 pieces of integrated circuit patterns P1<1> to P1<16> on the photo mask M1 and the 9 pieces of integrated circuit patterns P2<1> to P2<9> on the photo mask M2 are transferred onto the wafer W with one arrow and one column being shifted from each other.

Herein, the least common multiple in the X axis direction of the numbers of the integrated circuit patterns which are provided on the photo mask M1 and the photo mask M2 is 12, and the least common multiple in the Y axis direction of the numbers of the integrated circuit patterns is 12. Therefore, when the exposure processes of the photo masks M1 and M2 are completed, it is possible to realize 144 pieces of combinations of the first identifier F1 and the second identifier F2, which number is a product of the least common multiple in the X axis direction and the least common multiple in the Y direction of the integrated circuit patterns which are provided on the photo mask M1 and the photo mask M2, as shown in FIG. 2.

For example, in FIG. 2, the individual identifier ID[1] of the semiconductor integrated circuit IC[1] is “11” from a combination of “1” as the first identifier F1 and “1” as the second identifier F2. In addition, the individual identifier ID[5] of the semiconductor integrated circuit IC[5] is “21” from a combination of “1” as the first identifier F1 and “2” as the second identifier F2. Similarly, the individual identifiers ID[1] to ID[144] of the respective semiconductor integrated circuits IC[1] to IC[144] are constituted from combinations of the first identifier F1 and the second identifier F2, respectively.

Accordingly, all the individual identifiers ID[1] to ID[144] of the semiconductor integrated circuits IC[1] to IC[144] on the same wafer W are different from each other as shown in FIG. 2, and even if no process of performing such as marking is added so as to identify the arrangement positions, it is possible to identify the arrangement positions of the 144 pieces of the semiconductor integrated circuits IC[1] to IC[144] even in the semiconductor integrated circuit after having packaged.

As described above, if in order to produce individual identifiers ID[1] to ID[n] comprising different combinations on the n pieces of semiconductor integrated circuits IC[1] to IC[n] which are produced on a wafer W, respectively, the number of photo masks which are used for producing the individual identifiers and the numbers of the integrated circuit patterns in the X axis direction and in the Y axis direction on the respective photo masks are calculated such that the product of the least common multiples in the X axis direction and in the Y axis direction of the integrated circuit patterns which are produced on at least two or more photo masks that are employed for producing individual identifiers exceeds the number of the semiconductor integrated circuits that are formed on a same wafer, it is possible to produce the semiconductor integrated circuit IC[k] of this first embodiment on a wafer efficiently.

Herein, the number of photo masks for producing individual identifiers, the number of integrated circuit patterns in the X axis and Y axis direction on the respective photo masks, and the number of semiconductor integrated circuits that are produced on the same wafer W are not limited to the above, and it is possible to take appropriately arbitrary values in accordance with the number of semiconductor integrated circuits which are produced on the same wafer W.

For example, a case where two sheets of photo masks M1 and M2 for producing individual identifiers are employed in S times exposure processes are considered. In this case, if the photo mask M1 on which totally 25 pieces of integrated circuit patterns with 5 pieces arranged in the X axis direction and 5 pieces arranged in the Y axis direction are mounted and the photo mask M2 on which totally 49 pieces of integrated circuit patterns with 7 pieces arranged in the X axis direction and 7 pieces arranged in the Y axis direction are mounted are employed, the least common multiple of the integrated circuit pattern numbers in the X axis direction becomes 35 while the least common multiple of the integrated circuit pattern numbers in the Y axis direction becomes 35, thereby it is possible to identify the arrangement positions of semiconductor integrated circuits of the number up to 1225 pieces, which number is a product of the two numbers.

In addition, a case where three photo masks M1, M2, and M3 for producing individual identifiers are employed in the S times exposure processes is considered. In this case, when a photo mask M1 on which totally 9 pieces of integrated circuit patterns with 3 pieces arranged in the X axis direction and 3 pieces arranged in the Y axis direction are mounted, and a photo mask M2 on which totally 16 pieces of integrated circuit patterns with 4 pieces arranged in the X axis direction and 4 pieces arranged in the Y axis direction are mounted, and a photo mask M3 on which totally 25 pieces of integrated circuit patterns with 5 pieces arranged in the X axis direction and 5 pieces arranged in the Y axis direction are mounted are employed, the least common multiple of the integrated circuit pattern numbers in the X axis direction becomes 60 while the least common multiple of the integrated circuit pattern numbers in the Y axis direction becomes 60, thereby it is possible to identify the arrangement positions of the semiconductor integrated circuits of the number up to 3600 pieces, which is a product of the two numbers.

In this way, if the sheet number of the photo masks for producing individual identifiers and a product of the least common multiple of the integrated circuit pattern numbers in the X axis direction and the least common multiple of the integrated circuit pattern numbers in the Y axis direction are calculated, it is possible to produce the semiconductor integrated circuits IC[k] according to the first embodiment efficiently on a wafer W.

Next, the detailed structure of the first individual identifier ID[k], and the arrangement position identifying method on the same wafer W according to the first embodiment will be described.

As mentioned above, the individual identifier ID[k] is constituted by a resistor circuit which includes at least two resistor elements the resistance values of which can be electrically read out.

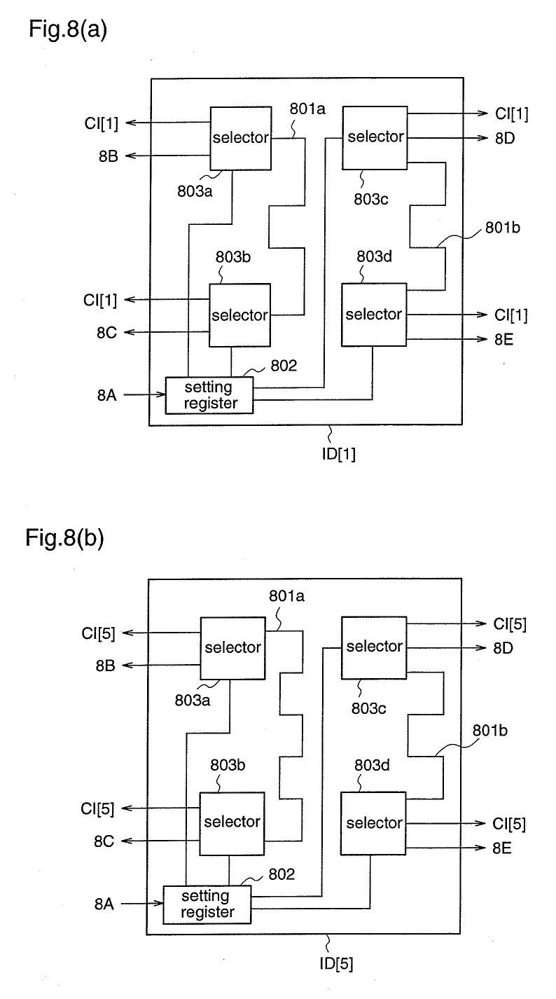

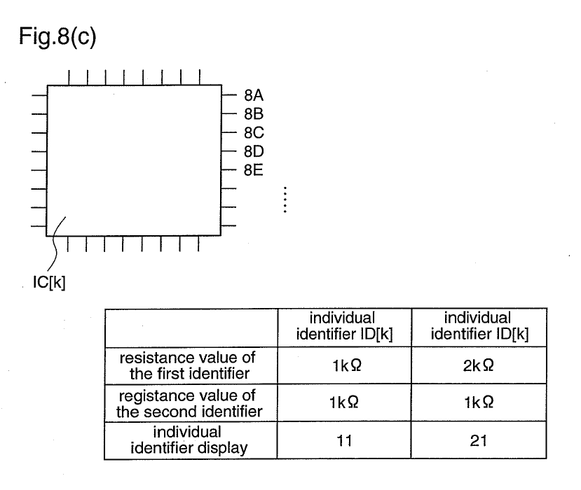

FIGS. 8(a) and 8(b) are diagrams representing a concrete construction of the individual identifier ID[k], where FIG. 8(a) represents the individual identifier ID[1] for the semiconductor integrated circuit IC[1] among the semiconductor integrated circuits IC[1] to IC[144] shown in FIG. 2, and FIG. 8(b) represents the individual identifier ID[5] for the semiconductor integrated circuit IC[5] among the semiconductor integrated circuits shown in FIG. 2.

The individual identifier ID[1] includes a first resistor element 801a which corresponds to the first identifier F1, a second resistor element 801b which corresponds to the second identifier F2, selectors 803a to 803d which switch the respective connection destinations of the first and the second resistor elements 801a, 801b, and setting registers 802 which set the output selections of the selectors 803a to 803d according to a switching signal which is inputted from the outside.

The first resistor element 801a is connected to the circuit portion CI[1] and the terminals 8B, 8C through selectors 803a, 803b, and the second resistor element 801b is connected to the circuit portion CI[1] and the terminals 8D, 8E through selectors 803c, 803d, respectively.

The individual identifier ID[5] has a resistance value of the first resistor element 801a that corresponds to the above-mentioned first identifier F1, that is different from the resistance value in the above-described individual identifier ID[1], and the other construction thereof are the same as in the above-described individual identifier ID[1].

As for the states of the terminals 8B to 8E, the read out selection mode for reading out the first resistor element 801a and the second resistor element 801b, or the read out non-selection mode can be set by switching the setting register 802, while at the read out non-selection mode, it is possible to utilize these terminals as general purpose terminals. Herein, without providing the setting register 802 and the selectors 803a, 803b, 803c, and 802d, it is possible to utilize the terminals 8B 8C, 8D, and 8E as read out oriented use terminals.

The individual identifier ID[1] and the individual identifier ID[5] constituted as described above are created by S times exposure processes shown in FIG. 4. That is, the first resistive element 801a and the second resistive element 801b are produced by previously determining the resistor elements which are to be assigned to the individual identifier ID[1] and the individual identifier ID[5], depicting their patterns onto the photo masks M1 and M2, and carrying out exposure processes using the photo masks M1 and M2. Further, the setting register 802 and the selector 803 can be produced appropriately in respective processes of S times exposure processes. Then, when the exposure is completed through the S times exposure processes, the first resistor element 801a and the second resistor element 801b are produced including wirings.

In addition, since usually there are variations in the resistance values, it is possible to prevent erroneous recognition of resistance values by selecting resistor elements which are assigned to the identifiers with considering variations in resistance values. In addition, the first identifier F1 and the second identifier F2 can be produced by previously arranging all the resistor patterns which are assigned to the first identifier F1 and the second identifier F2 at portions where the first identifier F1 and the second identifier F2 are arranged and connecting only required resistor patterns by exposure wirings.

In addition, the a-th identifier Fa may be constituted by an element which can replace for the resistor element, whose value can be electrically read out, such as a condenser or a reactance. Further, an individual identifier may be constituted by comprising a combination of identifiers, the respective bits of the identifiers being represented by resistance values corresponding to “0” and “1”, with assuming that the first identifier comprises m (m≧1) bits, the second identifier comprises n (n≧2) bits, . . . , and the a-th identifier comprises p (p≧2) bits, respectively.

Next, the method of identifying the arrangement position on the wafer W of the semiconductor substrate IC[k] that is constituted as described above will be described. Hereinafter, a case where 144 pieces of semiconductor integrated circuits IC[1] to IC[144] are formed on a wafer W as shown in FIG. 2 will be raised.

First of all, a read-out selection signal is inputted to the terminal 8A of the semiconductor integrated circuit IC[k] as an inspection target, and the setting of the setting register 802 is switched so that the connection destinations of the first resistor element 801a and the second resistor element 801b are the terminals 8B and 8C, and 8D and 8e, respectively. Then, a measurement apparatus such as a semiconductor inspection apparatus is connected to the terminal 8B and 8C, and the resistance value of the first resistor element 801a is electrically read out. Similarly, the resistance value between the terminal 8D and the terminal 8E is read out, and thus the resistance value of the second resistor element 801b is electrically read out.

In a case where the resistance value of the first resistor element 801a is 1 kΩ and also the resistance value of the second resistor element 801b is 1 kΩ, both of the first identifier F1[k] and the second identifier F2[k] are “1”, and thus it is found that the individual identifier ID[k] is “11”. In addition, by employing the correspondence table between the semiconductor integrated circuits IC[1] to IC[144] on the wafer W and the individual identifiers ID[1] to ID[144], it is found that the semiconductor integrated circuit IC[k] which is arbitrarily chosen is the semiconductor integrated circuit IC[1].

In addition, when the first resistor element 801a read out is 2 kΩ and the second resistor element 1b is 1 kΩ, the first identifier F1 is “2” and the second identifier F2 is “1”. That is, the individual identifier ID[k] is “21”, and therefore, it is found that the semiconductor integrated circuit IC[k] concerned is IC[5].

In addition, according to the semiconductor integrated circuit IC[k] of the present invention, even after having cut the semiconductor integrated circuit IC[1] or the semiconductor integrated circuit IC[5] from the wafer W and having packaged the integrated circuit IC, it is possible to identify the arrangement position on the wafer of the semiconductor integrated circuit IC[k] by reading out the resistance value of resistor elements.

FIG. 8(c) is a diagram illustrating a construction of a semiconductor integrated circuit after having packaged, and representing the relation between the output values of the terminals 8B to 8E and the individual identifiers. As shown in FIG. 8, by inputting a read out selection signal to the terminal 8A thereby to switch the setting register 802, it is possible to read out a combination of the resistance values of the first resistor element 101a and the second resistor element 801b using the terminals 8A, 8C, 8D, and 8E.

For example, when the resistance value between the terminal 8B and the terminal 8C is 1 kΩ and the resistance value between the terminal 8D and the terminal 8E is 1 kΩ as illustrated in FIG. 8(c), the individual identifier ID[k] is “11”, while when the resistance value between the terminal 8D and the terminal 8E is 2 kΩ and the resistance value between the terminal 8D and the terminal 8E is 1 kΩ, the individual identifier ID[k] is “21”. In this way, even for the semiconductor integrated circuit IC[k] after having packaged, it is possible to identify all the arrangement positions of the n pieces semiconductor integrated circuits ICs [k] which are formed on the same wafer W, without viewing such as surfaces of the semiconductor integrated circuits IC[1] and IC[2].

As described above, according to a transfer product fabrication method according to the first embodiment, there is provided, for example, a semiconductor integrated circuit fabrication method, which comprises repeating exposure processes S times each performing exposure for a desired pattern which comprises a plurality of integrated circuit patterns which are depicted on a photo mask onto a substrate, and performing exposure of a pattern of identifiers which are arranged in a lattice shape corresponding to the pattern of the plural integrated circuits onto a substrate in at least two exposure processes among the S times exposure processes, and in each of the at least two exposure processes, the patterns of identifiers are all made different from each other as well as the numbers of the identifiers on the identifier pattern which are exposed are made different from each other for each of the at least two exposure processes. Thereby, it is possible to produce an individual identifier comprising a combination of at least two identifiers onto each of the plural semiconductor integrated circuits produced on a wafer, and thereby it is possible to easily identify the arrangement position of the semiconductor integrated circuit on the wafer, without increasing fabrication processes.

Further, since the numbers of the integrated circuit patterns on the photo mask which are repeatedly employed in each of the at least two identifier pattern exposure processes are made such that the product of the least common multiple of the numbers in the X axis direction and the least common multiple of the numbers in the Y axis direction of the integrated circuit patterns which are depicted on the respective photo masks is larger than the number of all the semiconductor integrated circuits which are produced on the substrate, it is possible to add an individual identifier which can identify each semiconductor integrated circuit to all the semiconductor integrated circuits which are produced on the substrate, and thereby it is possible to efficiently produce a semiconductor integrated circuit having an individual identifier which can identifying it on a sheet of wafer.

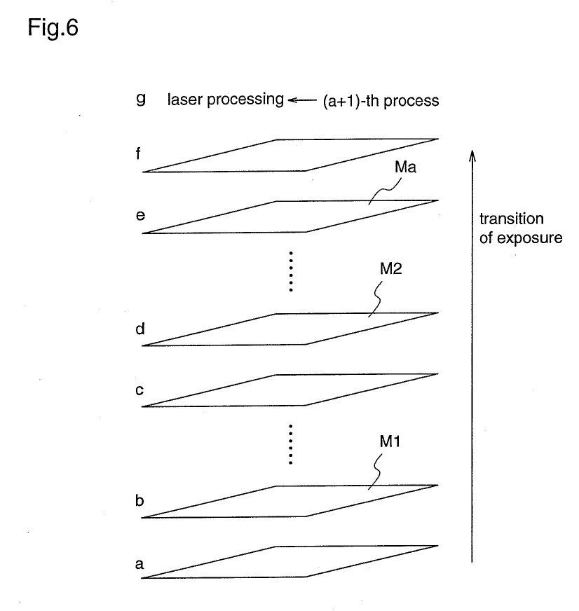

In addition, it is also possible to add, after having carried out the first exposure process (a) to the S-th exposure process (f), an (a+1)-th process (g) that processes the semiconductor integrated circuits IC[1] to IC[144] on the wafer W employing a laser device or an incur device, thereby adding identifier traces that can identify the wafer W to the integrated circuit, as shown in FIG. 6.

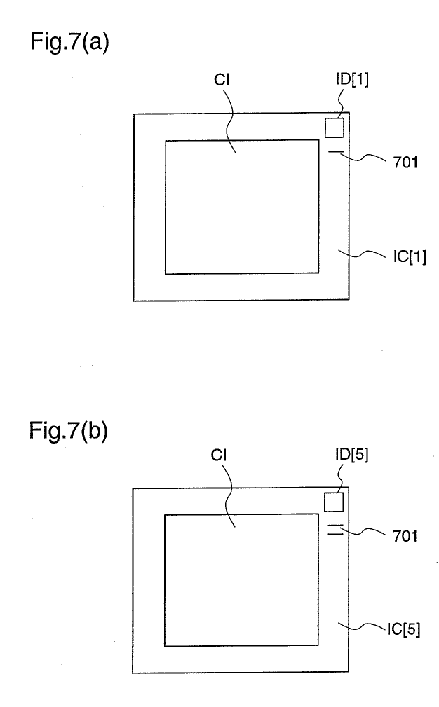

For example, in the (a+1)-th process (g), to each wafer as a processing target, dents which are different for each wafer are added. For example, at the processing to the wafer W1, an identifier dent is added as shown by 701 in FIG. 7(a), and at the processing to the wafer W2, two identifier dents are added as shown by 702 in FIG. 7(b). By adding such processes, the arrangement position of the semiconductor integrated circuit on the wafer W as well as the wafer W itself on which the semiconductor integrated circuit is produced can be identified, thereby enabling performing faulty analysis of a product at high precision.

Further, while in this first embodiment the individual identifier ID[k] comprising a combination of the first identifier F1 and the second identifier F2 is formed at a region outside the circuit portion CI, the individual identifier ID[k] may be formed directly at the circuit portion CI.

In addition, by constructing a system which displays the coordinate position on the wafer W of the semiconductor integrated circuit ID[k] when the value of the individual identifier ID[k] is inputted, it is possible to carry out faulty analysis of a product efficiently.

### Second Embodiment

Hereinafter, a transfer product, a fabrication method of a transfer product, and an arrangement position identifying method for plural transfer products which are produced on a single substrate will be described.

Hereinafter, a semiconductor integrated circuit is raised as an example of a transfer product similarly as in the first embodiment.

This second embodiment is constituted by forming the individual identifier ID[k] comprising a memory element circuit, i.e., employing memory elements as the first identifier F1 to the a-th identifier Fa in the semiconductor integrated circuit of the first embodiment.

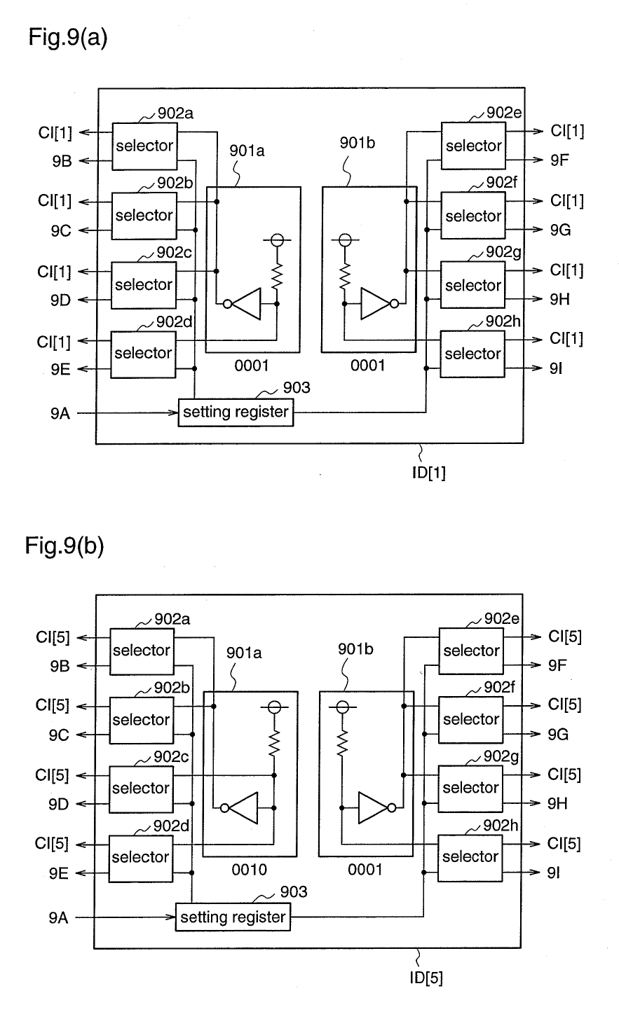

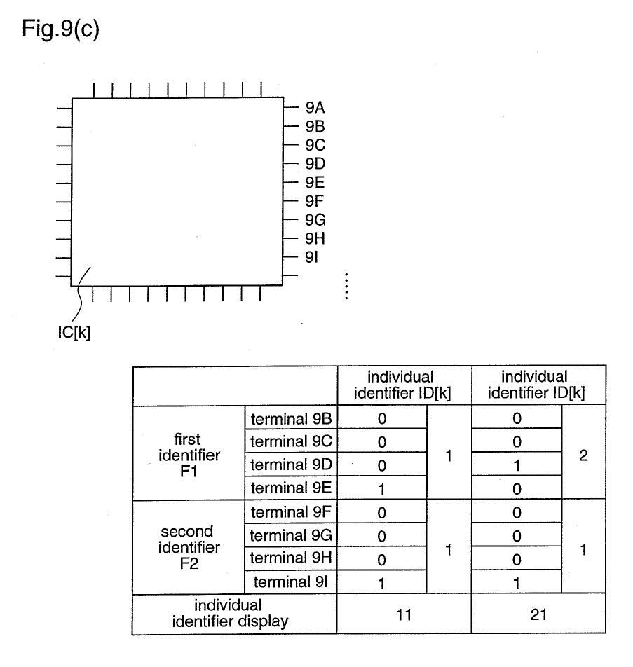

FIGS. 9(a) and 9(b) are diagrams illustrating the constructions of the individual identifier ID[n] according to the second embodiment, where FIG. 9(a) shows the individual identifier ID[1] for the semiconductor integrated circuit IC[1] among the semiconductor integrated circuits in the above-described first embodiment, and FIG. 9(b) shows the individual identifier ID[5] for the semiconductor integrated circuit IC[5], respectively.

The individual identifier ID[1] includes a first memory element 901a corresponding to the first identifier F1, a second memory element 901b corresponding to a second identifier F2, selectors 902a to 902h for switching the respective connection destinations of the first memory element 901a and the second memory element 901b, and a setting register for setting the output selection of the selectors 902a to 902h.

The first memory element 901a is connected to the circuit portion CI[1] and the terminals 9B to 9D via selectors 902a to 902d, and the second memory element 901b is connected to the circuit portion CI[1] and the terminals 9F to 9I via selectors 902e to 902h.

The terminals 9B to 9I can set the reading out selection mode of the individual identifier ID[k] or the reading out non-selection mode by switching the selectors 902a to 902h, and further, can utilize these terminals as general-purpose terminals by switching the input signal inputted to the setting register 903. The first memory element 901a and the second memory element 901b both comprise four bits, and the setting of the first memory element 901a is outputted to the terminals 9B to 9E via the selectors 902a to 902h, and the setting of the second memory element 901b is outputted to the terminals 9F to 9I. Those outputs are represented for its each bit, for example, by that “1” is set, when the gate of each bit is fixed to “H”.

In the individual identifier ID[1] shown in FIG. 9(a), the output of the terminal 9B is “0”, the output the terminal 9C “0”, the output the terminal 9D “0”, the output of the terminal 9E “1”, and thereby the first identifier F1 is expressed by “0001”. Similarly, the output of the terminal 9F is “0”, the output of the terminal 9G “0”, the output of the terminal 9H “0”, the output of the terminal 9I “0”, and thereby the second identifier F2 is expressed by “0001”.

Further, in the individual identifier ID[5] shown in FIG. 9(b), the output of the terminal 9B is “0”, the output the terminal 9C “0”, the output the terminal 9D “1”, the output of the terminal 9E “0”, and thereby the first identifier F1 is expressed by “0010”. Similarly, the output of the terminal 9F is “0”, the output of the terminal 9G “0”, the output of the terminal 9H “0”, the output of the terminal 9I “1”, and thereby the second identifier F2 is expressed by “0001”. Herein, it may be constituted such that “1” is set, when the gate of each bit is fixed to “L”.

The individual identifier ID [k] constituted as above is produced through S times exposure processes similarly as in the first embodiment. That is, the first memory element 901a and the second memory element 901b are produced through exposure processes employing photo masks M1 and M2, and the setting registers 903 and the selectors 901a to 902h are appropriately produced through S times exposure processes. Then, when the S times exposure processes are completed, the first memory element 901a and the second memory element 901b are produced including their wirings.

Further, when producing the first identifier F1 and the second identifier F2, it may be constructed such that plural gates are disposed at portions where the first identifier and the second identifier are arranged, only gates which are required are wired by employing exposure wirings, and thereby the first identifier and the second identifier are produced from the bit values corresponding to the numerals. In addition, when constituting the individual identifier ID[k] by the first identifier F1 to the a-th identifier Fa, the first identifier F1 may comprise m (m≧1) bits, the second identifier F2 may comprise n (n≧2) bits, . . . , and the a-th identifier Fa may comprise p (p≧2) bits, respectively.

When identifying the arrangement position on the wafer W of the semiconductor integrated circuit IC[k] according to the second embodiment, a signal indicating the readout selection mode is inputted to the setting register 903 through the terminal 9A, thereby to switch the connections of the first memory element 901a and the second memory element 901b to the terminals 9B to 9I. Then, with employing such as a semiconductor inspection device, the bit value which is assigned to the first identifier F1 is electrically read out by measuring the terminals 9B to 9E, and the bit value which is assigned to the first identifier F1 is electrically read out by measuring the terminals 9F to 9I. By reading out a combination of these individual bit values, it is possible to detect the individual identifier ID[k] of the semiconductor integrated circuit IC[k], thereby reading out the arrangement position information on the wafer W.

According to the semiconductor integrated circuit IC[k] of the second embodiment, even in the integrated circuit after having packaged, it is possible to identify the arrangement position of all the integrated circuits which are formed on the same wafer W.

FIG. 9(c) is a diagram illustrating a construction of the semiconductor integrated circuit IC[k], and representing the relation between the output values at the terminals 9B to 9I and the individual identifiers. As shown in FIG. 9, by that a read out selection signal is inputted to the terminal 9A thereby to switch the setting register 903, it is possible to read out a combination of the set values of the first memory element 901a and the second memory element 901b with using the terminals 9B to 9I.

For example, when the output values at the terminals 9B to 9E are 0, 0, 0, 1, and the output values of the terminals 9F to 9I are 0, 0, 0, 1, respectively, as shown in FIG. 9(c), the individual identifier ID[k] is “11”, while when the output values at the terminals 9B to 9E are 0, 0, 1, 0, and the output values of the terminals 9F to 9I are 0, 0, 0, 1, respectively, the individual identifier ID[k] is “21”. In this way, even in the semiconductor integrated circuit IC[k] after having packaged, it is possible to identify all the arrangement positions of the n pieces of semiconductor integrated circuits IC[k] which are formed on the same wafer W, without viewing such as surfaces of the semiconductor integrated circuits IC[1] or IC[5].

As described above, according to the transfer product fabrication method of the second embodiment, there is provided, for example, a semiconductor integrated circuit fabrication method, which comprises repeating exposure processes S times each performing exposure for a desired pattern which comprises plural integrated circuit patterns which are depicted on a photo mask onto a substrate, and performing exposure of a pattern of memory elements which are arranged in a lattice shape corresponding to the pattern of the plural integrated circuits onto a substrate in at least two exposure processes among the S times exposure processes, and in each of the at least two exposure processes, the patterns of the memory elements which are depicted on a sheet of photo mask are made different from each other as well as the numbers of the memory elements on the memory element pattern on a sheet of photo mask are made different from each other. Thereby, it is possible to produce an individual identifier comprising a combination of at least two memory elements onto each of the plural semiconductor integrated circuits produced on a wafer, and thereby it is possible to read out values of the individual identifier ID digitally, resulting in enhancement in the analysis precision when identifying the arrangement position of the semiconductor integrated circuit.

### Third Embodiment

The third embodiment of the preset invention is obtained by constituting the individual identifier ID[k] comprising a two dimensional code in the semiconductor integrated circuit of the first embodiment.

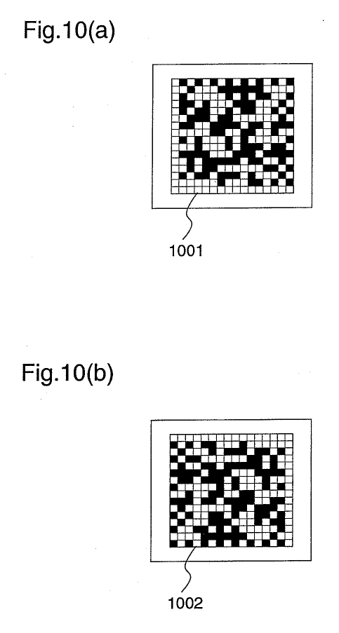

FIGS. 10(a) and 10(b) are diagrams illustrating a construction of the individual identifier ID[k] according to the third embodiment.

The individual identifier ID[k] according to the third embodiment is constituted by a two-dimensional code, and the first identifier F1 to the a-th identifier Fa comprise portion code patterns which constitute the two-dimensional code together.

The two-dimensional code has an arrangement position information on the wafer W. The production method of the two dimensional code comprises producing the first identifier F1 to the a-th identifier Fa using the photo masks M1 to Ma each having the circuit portion CI and a portion code pattern constituting part of the two dimensional code in the a (a≧2) times identifier pattern exposure processes, thereby forming the two dimensional code 1001 and the two dimensional code 1002 having the arrangement information on the wafer W with the first identifier F1, the second identifier F2, . . . , the a-th identifier Fa being overlapped with each other when the exposures are completed through the s times exposure processes.

When determining the arrangement position information of each respective integrated circuit ID[k], the individual identifier ID[k] is read out, and the content of the two-dimensional code is analyzed, thereby the arrangement position information is obtained.

As described above, according to the transfer product fabrication method of the third embodiment, there is provided, for example, a semiconductor integrated circuit fabrication method, which comprises repeating exposure processes S times each performing exposure for a desired pattern which comprises plural integrated circuit patterns which are depicted on a photo mask onto a substrate, and performing exposure of a pattern of portion codes which constitute parts of the two-dimensional codes which are arranged in a lattice shape corresponding to the pattern of the plural integrated circuits onto a substrate in at least two exposure processes among the S times exposure processes, and in each of the at least two exposure processes, the patterns of the portion codes which are depicted a sheet of the photo mask are made different from each other as well as the numbers of the portion codes on the portion code pattern on a sheet of photo mask is made different from each other. Thereby, it is possible to produce an individual identifier comprising a two-dimensional code onto each of the plural semiconductor integrated circuits produced on a wafer, and thereby it is possible to increase the stability concerning the administration of the arrangement position information with excluding a danger of the content of the two-dimensional code being read by a person who is not controlling the content.

In addition, while in the third embodiment a method that constitute the individual identifier 1001 and the individual identifier 1002 using the two-dimensional codes is described, these may be constituted by those which can replace the two-dimensional code such as bar code, geometric patterns, and figure patterns, with the same effects described above.

While the above-described first to third embodiments are illustrated with reference to semiconductor integrated circuits, the present invention can be applied to fabrications of those employing exposure processes such as fabrications of panels, MEMS (Microelectro Mechanical Systems), thin films, or films, or fabrications of those using printing processes such as fabrications of a color printer or a print circuit board.

### APPLICABILITY IN INDUSTRY

According to the transfer product, transfer product fabrication method, and transfer product arrangement position identification method of the present invention, it is possible to identify the arrangement position of each product for the plural products which are provided with the on-substrate arrangement position information and which are produced on the same substrate, and thereby it is effective in performing faulty analysis of products.

1-8. (canceled)

9. A transfer product fabrication method for fabricating a plurality of transfer products on a same substrate, which comprises repeating transfer steps each transferring a desired transfer pattern which comprises plural individual patterns arranged in a lattice shape onto a substrate with shifting the position thereof plural times, which further comprises:
producing an arrangement position information representing the arrangement position on the substrate of the transfer product onto each of the transfer products which are produced on the substrate through the at least two transfer steps.

10. A transfer product fabrication method as defined in claim 9, wherein
in each transfer step of the at least two transfer steps, respective identifiers forming the arrangement position information are produced for each of the plural transfer products which are produced on the substrate.

11. A transfer product fabrication method as defined in claim 10, wherein
the at least two transfer steps transfer identifier patterns which are arranged in a lattice shape in a desired transfer pattern corresponding to the respective individual patterns,
the identifier patterns are all different for each individual pattern, and
the number of the individual patterns which are transferred in each of the at least two transfer processes is different in each of the at least two transfer processes.

12. A transfer product fabrication method of a transfer product as defined in claim 11, wherein
the product of the least common multiple of the numbers in the X axis direction and the least common multiple of the numbers in the Y axis direction of the individual patterns which are transferred at one time in each of the at least two transfer processes is larger than the total number of the transfer products which are produced on the same substrate.

13. A transfer product fabrication method as defined in claim 10, which further comprises:
producing resistor elements having inherent resistance values in respective steps of the at least two transfer steps, and
adding, to each of the plural transfer products which are produced on the substrate, the arrangement position information which comprises a combination of the at least two resistor elements produced, respectively.

14. A transfer product fabrication method as defined in claim 10, further comprising:
producing memory elements which are constituted by one or more bits in each step of the at least two transfer steps, and
adding, to each of the plural transfer products which are produced on the substrate, the arrangement position information which comprises a combination of the values of the at least two memory elements produced.

15. A transfer product fabrication method as defined in claim 10, which further comprises:
producing a code pattern which forms a part of a two-dimensional code which can be recognized from outside in respective steps of the at least two transfer steps, and
adding, to each of the plural transfer products which are produced on the substrate, the arrangement position information that is represented by a two-dimensional code which is a combination of the at least two code patterns formed.

16. A transfer product fabrication method as defined in claim 9, which further comprises:
adding, to each of the plural transfer products, substrate information that represents the substrate on which the transfer product is formed identifiably.

17. A transfer product arrangement position identifying method for identifying the transfer product arrangement position on the same substrate for the transfer products which are produced on the same substrate, comprising:
carrying out a transfer process that transfers a desired transfer pattern that has arranged plural individual patterns in a lattice shape onto a substrate, with shifting the position on the substrate repeatedly, which further comprises:
reading out a combination of at least two identifiers which are produced on the plural transfer products in each of the at least two transfer processes, so as to identify the arrangement position on the substrate.

18. A transfer product arrangement position identifying method as defined in claim 17, wherein
the identifier is represented by resistance values which are produced in respective processes of the at least two transfer processes, and
the arrangement position is identified on the basis of a combination of resistance values of at least two resistor elements.

19. A transfer product arrangement position identifying method as defined in claim 17, wherein
the identifier is represented by values which are inherent to the memory elements which values are constituted by one or more bits respectively, and which values are produced in respective processes of the at least two transfer processes, and further comprises:
identifying the arrangement position on the substrate on the basis of the combination of values of the at least two memory elements.

20. A transfer product arrangement position identifying method as defined in claim 17, wherein
the identifier is one which is represented by code patterns which form parts of the two-dimensional code which are produced in the respective processes of the at least two transfer processes, and further comprises:
identifying the arrangement position on the substrate on the basis of the information that is possessed by the two-dimensional code which comprises a combination of the at least two code patterns.
